(19) United States
(12) Patent Application Publication
(10) Pub. No.: US 2025/0262833 A1
(43) Pub. Date: Aug. 21, 2025

(54) SHAPING DEVICE

(71) Applicant: Murata Manufacturing Co., Ltd., Kyoto-fu (JP)

(72) Inventors: Toru KOMATSU, Nagaokakyo-shi (JP); Akihiko KAMADA, Nagaokakyo-shi (JP); Tadashi NOMURA, Nagaokakyo-shi (JP)

(21) Appl. No.: 19/197,351

(22) Filed: May 2, 2025

Related U.S. Application Data
(63) Continuation of application No. PCT/JP2023/038478, filed on Oct. 25, 2023.

(30) Foreign Application Priority Data
Nov. 7, 2022 (JP) 2022-178389

(51) Int. Cl. B30B 9/28; B30B 15/28; B30B 15/34

(52) U.S. Cl. CPC B30B 9/28; B30B 15/287; B30B 15/34

(57) ABSTRACT

The shaping device includes a pushing tool that pushes a plate-shaped object, which is disposed in such a manner that one main surface thereof faces upward. from a side of the object, and a heating unit that heats the object.

### CROSS-REFERENCE TO RELATED APPLICATIONS

This application is a continuation of PCT Patent Application No. PCT/JP2023/038478, filed Oct. 25, 2023, which claims priority to Japanese Patent Application No. 2022-178389 filed Nov. 7, 2022. These documents are herein incorporated in their entireties by reference.

### TECHNICAL FIELD

The present disclosure relates to a shaping device.

### BACKGROUND ART

Japanese Patent Application Laid-Open No. 2002-76580 (PTL 1) discloses a warp correction device for correcting warpage of a plate-shaped object. According to PTL 1, this device can be used to correct warpage deformation to a uniform flat shape without causing any surface damage to a printed resin substrate. This device includes a hot water tank and a cooling water tank. This device includes a press unit. The press unit includes an upper die having a downwardly convex surface and a lower die having a downwardly concave surface. The warpage deformation of the printed resin substrate is corrected by sandwiching the printed resin substrate between the upper die and the lower die in hot water. The printed resin substrate in high temperature is carried into cooling water tank and held between an upper warp return prevention plate and a lower warp return prevention plate.

### BRIEF SUMMARY

### Technical Problem

In the device described in PTL 1, a jig having a shape suitable for the correction amount is required. In the case of correcting an object having a plurality of shapes, it is necessary to prepare a plurality of types of jigs in advance for each shape. In addition, when the desired deformation amount changes, it is necessary to replace the jig each time, which makes the operation complicated.

Therefore, an object of the present disclosure is to provide a shaping device that can easily deal with a change in a desired deformation amount.

### Solution to Problem

In order to achieve the above object, a shaping device according to the present disclosure includes a pushing tool that pushes a plate-shaped object, which is disposed in such a manner that one main surface thereof faces upward, from a side of the object, and a heating unit that heats the object.

### Advantageous Effects

According to the present disclosure, since the shaping device includes a pushing tool that pushes the object from a side thereof, it is possible to easily deal with a change in the desired deformation amount.

### BRIEF DESCRIPTION OF DRAWINGS

FIG. 1 is a conceptual diagram illustrating a shaping device according to a first embodiment of the present disclosure.

FIG. 2 is a plan view illustrating an object supporting unit provided in the shaping device according to the first embodiment of the present disclosure.

FIG. 3 is a cross-sectional view illustrating a first state of the object supporting unit provided in the shaping device according to the first embodiment of the present disclosure.

FIG. 4 is a cross-sectional view illustrating a second state of the object supporting unit provided in the shaping device according to the first embodiment of the present disclosure.

FIG. 5 is an explanatory view illustrating a state in which an object is disposed on the object supporting unit of the shaping device according to the first embodiment of the present disclosure.

FIG. 6 is an explanatory diagram illustrating a state in which the object is heated by a heating unit of the shaping device according to the first embodiment of the present disclosure.

FIG. 7 is an explanatory view illustrating a state in which a pushing tool is moved to sandwich the object in the shaping device according to the first embodiment of the present disclosure.

FIG. 8 is an explanatory view illustrating a state in which the object held by the pushing tool is cooled in the shaping device according to the first embodiment of the present disclosure.

FIG. 9 is an explanatory view illustrating a state in which a plurality of support pins are lifted and the pushing tool is moved backward after cooling is completed in the shaping device according to the first embodiment of the present disclosure.

FIG. 10 is a conceptual diagram illustrating a shaping device according to a second embodiment of the present disclosure.

FIG. 11 is an explanatory diagram illustrating a state in which an object is deformed by moving a pushing tool forward in the shaping device according to the second embodiment of the present disclosure.

FIG. 12 is an explanatory diagram illustrating how the position of an outer edge of the object in the height direction is adjusted using a pressing member in the shaping device according to the second embodiment of the present disclosure.

FIG. 13 is an explanatory view illustrating a state in which the pressing member is lifted and a plurality of support pins are lowered in the shaping device according to the second embodiment of the present disclosure.

FIG. 14 is an explanatory diagram illustrating how the deformation amount of the object is adjusted using the pushing tool in the shaping device according to the second embodiment of the present disclosure.

FIG. 15 is an explanatory diagram illustrating another method of using the pressing member in the shaping device according to the second embodiment of the present disclosure.

FIG. 16 is an explanatory diagram illustrating a state in which a plurality of support pins are lowered when the object is sandwiched by the pushing tools and held by the same in the shaping device according to the second embodiment of the present disclosure.

FIG. 17 is a conceptual diagram illustrating a shaping device according to a third embodiment of the present disclosure.

FIG. 18 is an explanatory diagram illustrating a state in which an object is disposed on an object supporting unit in the shaping device according to the third embodiment of the present disclosure.

FIG. 19 is a conceptual diagram illustrating a shaping device according to a fourth embodiment of the present disclosure.

FIG. 20 is a conceptual diagram illustrating a modification of the shaping device according to the fourth embodiment of the present disclosure.

FIG. 21 is a conceptual diagram illustrating a shaping device according to a fifth embodiment of the present disclosure.

FIG. 22 is a conceptual diagram illustrating a first modification of the shaping device according to the fifth embodiment of the present disclosure.

FIG. 23 is a conceptual diagram illustrating a second modification of the shaping device according to the fifth embodiment of the present disclosure.

FIG. 24 is a conceptual diagram illustrating a third modification of the shaping device according to the fifth embodiment of the present disclosure.

FIG. 25 is a conceptual diagram illustrating a fourth modification of the shaping device according to the fifth embodiment of the present disclosure.

FIG. 26 is a conceptual diagram illustrating a shaping device according to a sixth embodiment of the present disclosure.

FIG. 27 is a conceptual diagram illustrating a modification of the shaping device according to the sixth embodiment of the present disclosure.

FIG. 28 is an explanatory diagram illustrating a state in which an object is disposed on an object supporting unit in the shaping device according to a sixth embodiment of the present disclosure.

FIG. 29 is an explanatory view illustrating a state in which the object is deflected by lifting a pressing member and moving a pushing tool forward in the shaping device according to the sixth embodiment of the present disclosure.

FIG. 30 is an explanatory diagram illustrating a state in which an object is disposed on an object supporting unit in a modification of the shaping device according to the sixth embodiment of the present disclosure.

FIG. 31 is an explanatory view illustrating a state in which an object is deflected by lifting a pressing member and moving a pushing tool forward in a modification of the shaping device according to the sixth embodiment of the present disclosure.

FIG. 32 is a plan view illustrating an object supporting unit provided in a shaping device according to a seventh embodiment of the present disclosure.

FIG. 33 is a cross-sectional view taken along line XXXIII-XXXIII in FIG. 32.

FIG. 34 is a first explanatory diagram illustrating an operation of a pushing unit provided in the shaping device according to the seventh embodiment of the present disclosure.

FIG. 35 is a second explanatory diagram illustrating an operation of the pushing unit provided in the shaping device according to the seventh embodiment of the present disclosure.

FIG. 36 is a plan view illustrating an object supporting unit provided in a shaping device according to an eighth embodiment of the present disclosure.

FIG. 37 is a cross-sectional view taken along line XXXVII-XXXVII in FIG. 36.

FIG. 38 is a plan view illustrating an object supporting unit in which a pushing unit is provided only at one corner.

FIG. 39 is a plan view illustrating an object supporting unit in which a pushing unit is provided only at two corners.

### DETAILED DESCRIPTION

The dimensional ratios illustrated in the drawings are not necessary to faithfully represent actual dimensions, and the dimensional ratios may be exaggerated for convenience of description. In the following description, when referring to the concept of top or bottom, it does not necessarily mean absolute top or bottom, but may mean relative top or bottom in the illustrated posture.

The concept of “shaping” as used herein includes removing an undesired warpage from an object to make the object flat or reducing the warpage. Further, the concept of “shaping” also includes intentionally deforming an object into a desired shape when the object is not in the desired shape.

### First Embodiment

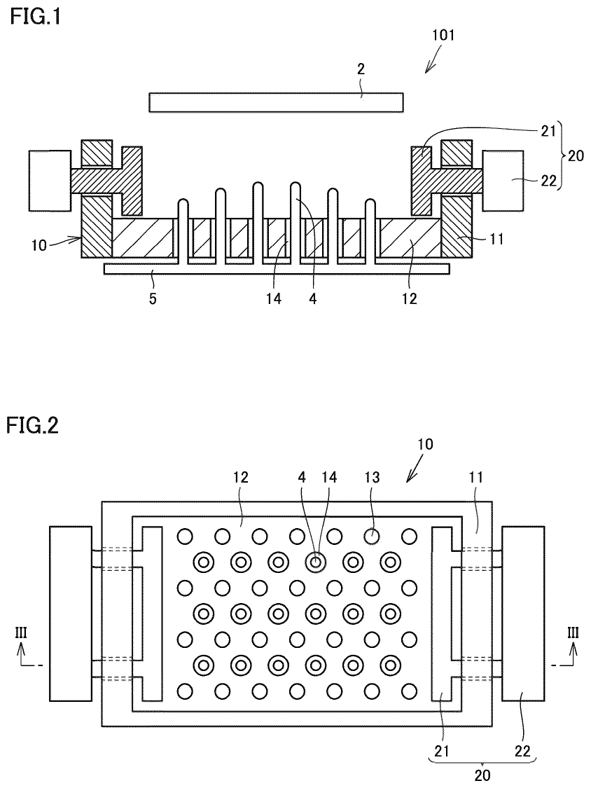

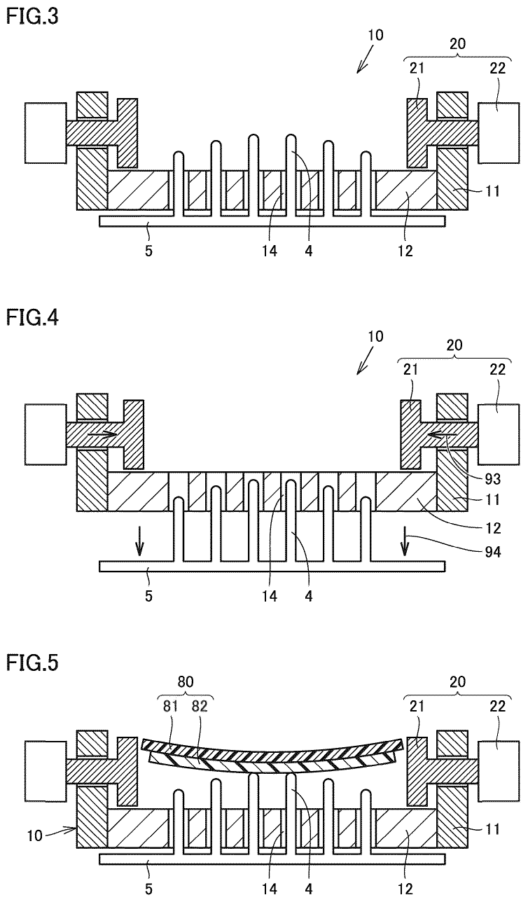

A shaping device according to a first embodiment of the present disclosure will be described with reference to FIGS. 1 to 5. FIG. 1 illustrates a shaping device 101 according to the present embodiment. Shaping device 101 includes an object supporting unit 10 and a heating unit (e.g., a heater) 2. FIG. 2 illustrates object supporting unit 10 as viewed directly from the top. Object supporting unit 10 includes a pushing unit 20. Each pushing unit 20 includes a pushing tool 21 and a driving member 22. FIG. 3 is a cross-sectional view of object supporting unit 10 in a first state, and FIG. 4 is a cross-sectional view of object supporting unit 10 in a second state. FIG. 5 illustrates a state in which an object 80 is disposed on object supporting unit 10. In the present embodiment, object 80 includes a first resin layer 81 and a second resin layer 82. First resin layer 81 is a plate-shaped member formed of resin. Second resin layer 82 is disposed to cover a part of one surface of first resin layer 81. Object 80 illustrated in the present embodiment is as an example, and it may have other structures. Object 80 may include, for example, a material layer other than a resin layer, or may be composed of three or more layers. Object 80 is not limited as long as it is a plate-shaped object.

Shaping device 101 includes a pushing tool 21 that pushes the plate-shaped object 80, which is disposed in such a manner that one main surface thereof faces upward, from a side of object 80, and a heating unit 2 that heats object 80.

Furthermore, in the present embodiment, shaping device 101 includes a plurality of support pins 4 that supports object 80. Object supporting unit 10 includes an outer periphery 11 and a base 12. Base 12 is surrounded by outer periphery 11. Base 12 is provided with at least one suction port 13 and a plurality of through holes 14. The plurality of support pins 4 pass through the plurality of through holes 14, respectively.

Heating unit 2 may be configured to irradiate halogen light, for example. Heating unit 2 may be, for example, an infrared heater. Heating unit 2 may be configured to blow warm air, for example. The heating method by heating unit 2 may be any method other than the method described in the present embodiment.

The operation of shaping device 101 according to the present embodiment will be described with reference to FIGS. 5 to 9.

First, as illustrated in FIG. 5, object 80 is disposed on object supporting unit 10. At this time, object 80 is warped. Object 80 is supported by the plurality of support pins 4.

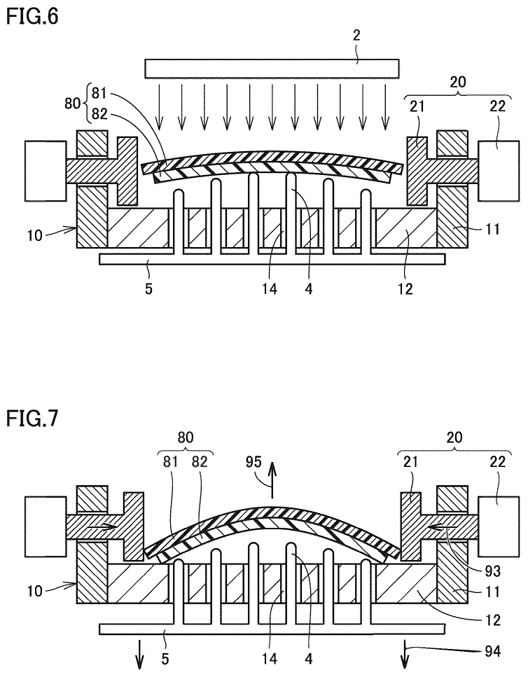

Next, as illustrated in FIG. 6, object 80 is heated using heating unit 2. Object 80 is softened by the heating, which reduces warpage, and then the object is supported by the plurality of support pins 4.

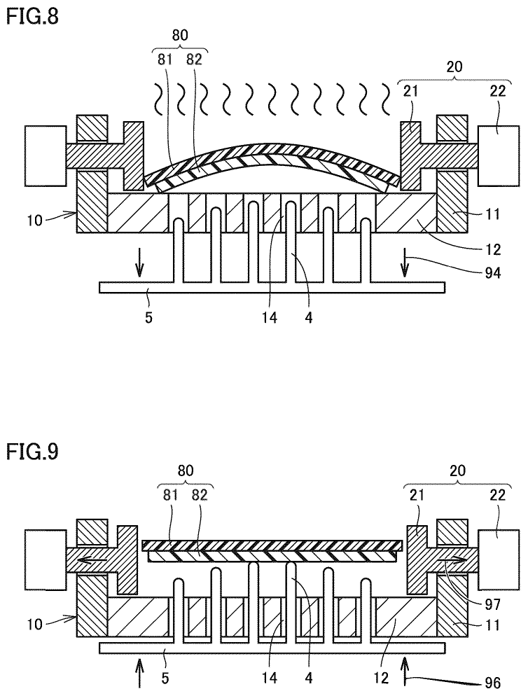

As illustrated in FIG. 7, pushing unit 20 is operated. Specifically, each pushing tool 21 is moved in the direction of an arrow 93 to sandwich object 80. Object 80 is sandwiched by pushing tools 21 and deflected in the direction of an arrow 95. In this state, the plurality of support pins 4 are lowered as indicated by an arrow 94. By lowering a support pin holding member 5, the plurality of support pins 4 can be lowered at the same time. As illustrated in FIG. 8, the plurality of support pins 4 are further lowered. In FIG. 8, the plurality of support pins 4 are all separated from object 80. Object 80 is sandwiched by pushing tools 21 in a deflected state and held by the same. In this state, the cooling is performed. After the cooling is completed, the plurality of support pins 4 are lifted as indicated by an arrow 96 in FIG. 9. At this time, each pushing tool 21 is moved backward as indicated by an arrow 97. Each pushing tool 21 is moved away from object 80. Object 80 is supported by the plurality of support pins 4.

Even if object 80 is initially deflected in a downward convex direction as illustrated in FIG. 5, after heating, the object can be made flat as illustrated in FIG. 9 by temporarily deforming the object in an upward convex direction with pushing tool 21 as illustrated in FIGS. 7 to 8 and then cooling the object. However, this is merely an example. The heating conditions, the pushing amount by pushing tool 21, the holding time by pushing tool 21, and the like may be adjusted according to the shape of object 80 to be finally obtained.

In the present embodiment, since pushing tool 21 that pushes object 80 from a side is provided, it is possible to realize a shaping device that can easily deal with a change in the target correction amount.

In the present embodiment, object supporting unit 10 includes a base 12. Although base 12 is not essential, as described in the present embodiment, it is preferable to provide base 12 to support object 80. According to this configuration, object 80 can be stably supported.

In the present embodiment, base 12 includes a cooling unit (e.g., a cooler). Although the cooling unit is not essential, as described in the present embodiment, it is preferable that base 12 includes a cooling unit to cool object 80. According to this configuration, object 80 can be efficiently cooled.

In the present embodiment, base 12 is provided with at least one suction port 13, and suction port 13 is connected to a suction device (not shown). As described in the present embodiment, it is preferable that shaping device 101 includes a suction device to suck object 80 downward. According to this configuration, object 80 can be held by suction.

In the present embodiment, shaping device 101 includes a plurality of support pins 4 that support object 80. As described in the present embodiment, it is preferable that shaping device 101 includes a plurality of support pins 4 protruding upward to support object 80. According to this configuration, object 80 can be held by the plurality of support pins 4. Further, it is preferable that the plurality of support pins 4 are movable in the vertical direction. According to this configuration, object 80 can be lifted or lowered by the plurality of support pins 4.

With respect to the lifting or lowering of the plurality of support pins 4, it is described in the present embodiment that all the plurality of support pins 4 are integrated and are lifted or lowered simultaneously, but the present disclosure is not limited thereto. For example, each of the plurality of support pins 4 may be lifted or lowered independently.

As described in the present embodiment, assuming an imaginary plane that connects all upper ends of the plurality of support pins 4, the imaginary plane is preferably convex upward. According to this configuration, object 80 can be appropriately supported.

In the present embodiment, it is described that object 80 has a rectangle shape, the shape of object 80 is not limited to a rectangle. Object 80 may have a square shape, a polygonal shape, a circular shape, an elliptical shape, or any other shape. The configuration of a shaping device, which is particularly suitable for shaping an object 80 having a square shape, will be described in detail in a seventh embodiment and an eighth embodiment.

### Second Embodiment

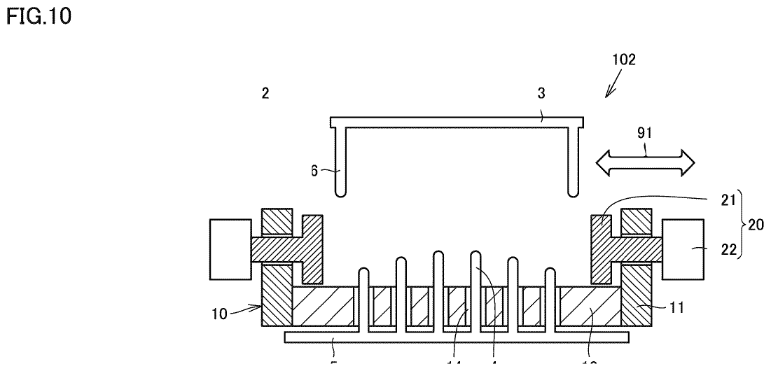

A shaping device according to a second embodiment of the present disclosure will be described with reference to FIG. 10. FIG. 10 illustrates a shaping device 102 according to the present embodiment. Shaping device 102 includes an object supporting unit 10, a heating unit 2, and a pressing member 3. Heating unit 2 and pressing member 3 are movable in the lateral direction, for example, as indicated by an arrow 91. Heating unit 2 and pressing member 3 can be moved right above object supporting unit 10 as necessary. Shaping device 102 includes pressing member 3, and pressing member 3 is provided with protrusions 6 extending downward, and when the tip of each projection 6 is brought into contact with object 80, object 80 is pressed downward.

The operation of shaping device 102 according to the present embodiment will be described with reference to FIGS. 5, 6, and FIGS. 11 to 14.

First, as illustrated in FIG. 5, object 80 is disposed on object supporting unit 10. At this time, object 80 is warped. Object 80 is supported by the plurality of support pins 4.

Next, as illustrated in FIG. 6, object 80 is heated by using heating unit 2. Object 80 is softened by the heating, which reduces warpage, and then the object is supported by the plurality of support pins 4.

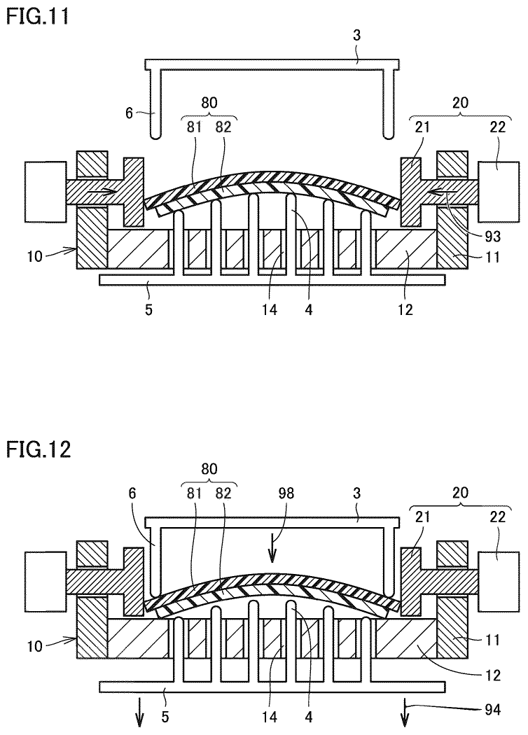

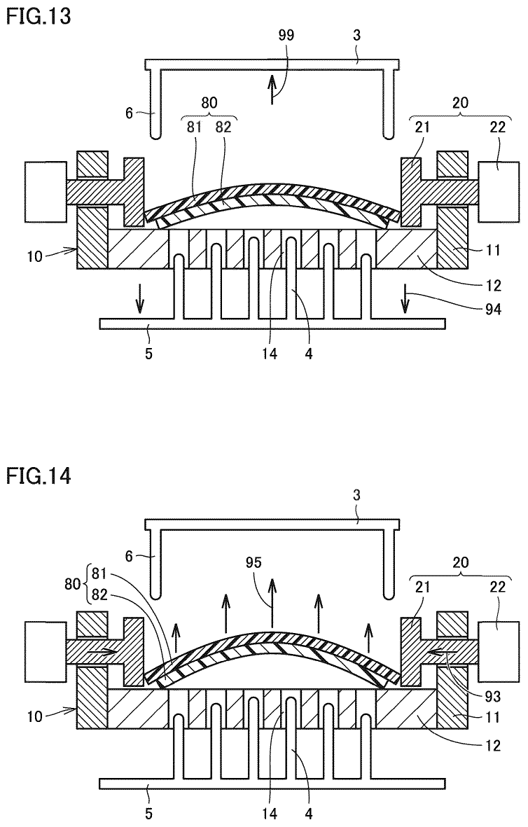

As illustrated in FIG. 11, pushing tool 21 is moved forward in the direction of arrow 93 to deform object 80. Object 80 is deformed into an upward convex shape. The upper ends of the plurality of support pins 4 are arranged along the deformed object 80. As indicated by an arrow 98 in FIG. 12, pressing member 3 is lowered to press against the outer edge of object 80 to adjust the position of the outer edge of object 80 in the height direction. At this time, it is desirable to adjust the position of the outer edge of object 80 in FIG. 11 so that the position of a left edge portion of object 80 in the height direction is the same as the position of a right edge portion in the height direction. When adjusted in this way, a force is applied to the left edge portion and the right edge portion of object 80 at the same position in the height direction, respectively, and thereby object 80 can be deflected in a state closer to symmetry. In this state, object 80 is sandwiched by pushing tools 21 and held by the same. As indicated by an arrow 99 in FIG. 13, pressing member 3 is lifted, and the plurality of support pins 4 are lowered. As indicated by arrow 93 in FIG. 14, pushing tool 21 is moved forward to adjust the deformation amount of object 80. Object 80 is deflected in the direction of arrow 95 to adjust the deformation amount thereof. In this manner, object 80 can have a desired shape.

Also, the same effects as those described in the first embodiment can be obtained in the present embodiment. Further, since shaping device 102 includes pressing member 3, object 80 can be more reliably held at a desired position.

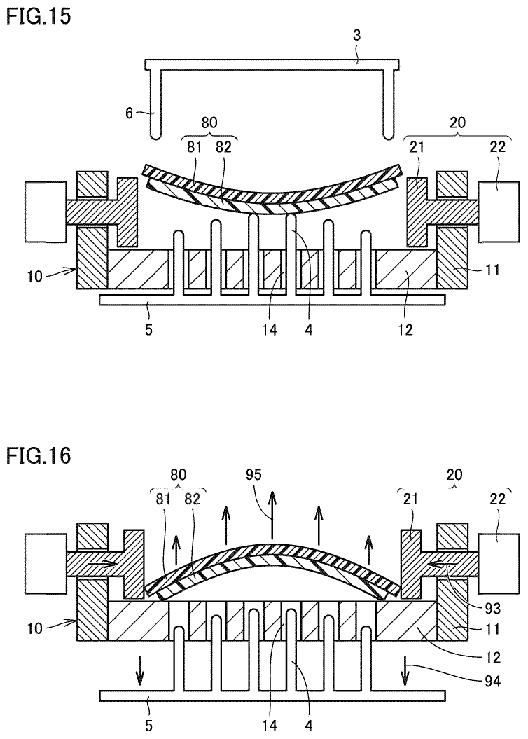

Another application of pressing member 3 will be described with reference to FIG. 15. In FIG. 15, object 80 has not been sufficiently deformed by the heating, and the outer edge of object 80 still remains higher than the upper end of pushing tool 21. Since the outer edge of object 80 cannot be pushed by pushing tool 21 even if it is moved forward, the application of pressing member 3 is considered as a countermeasure. In the state illustrated in FIG. 15, the position of the outer edge of object 80 can be lowered by lowering pressing member 3 to press the outer edge of object 80 downward, and thereby object 80 can be sandwiched and held by pushing tools 21 by moving pushing tools 21 forward.

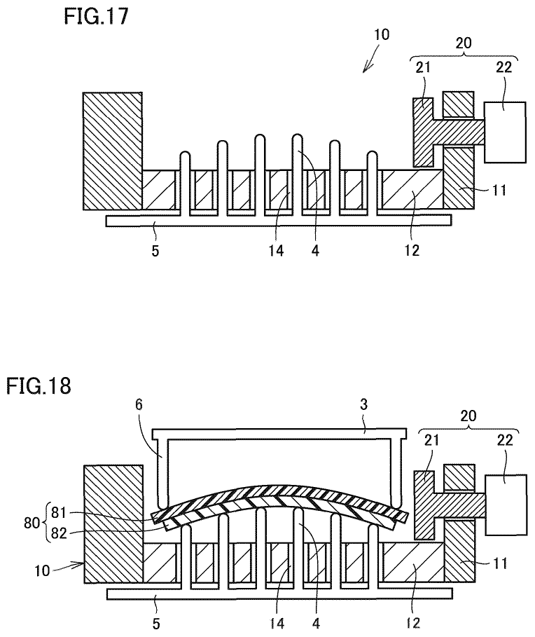

When object 80 is sandwiched and held by pushing tools 21, as indicated by an arrow 94 in FIG. 16, the plurality of support pins 4 can be lowered to be completely separated from object 80. By moving pushing tool 21 forward in the direction of arrow 93, object 80 is deflected in the direction of arrow 95. In this state, the cooling may be performed.

The shape of protrusions 6 of pressing member 3 is not limited to the example illustrated in FIG. 10. Protrusions 6 are not necessarily fixed, but may be configured to be replaceable in any number and at any position. The length of each protrusion 6 may be extendable and contractible. Pressing member 3 can have various shapes by replacing each of protrusions 6 or by changing the length of each of protrusions 6.

### Third Embodiment

A shaping device according to a third embodiment of the present disclosure will be described with reference to FIGS. 17 and 18. FIG. 17 illustrates an object supporting unit 10 of the shaping device according to the present embodiment. In the shaping device according to the present embodiment, a pushing unit 20 is provided only at one side of object supporting unit 10. FIG. 18 illustrates a state in which object 80 is disposed in the shaping device according to the present embodiment. On the side opposite to pushing unit 20, object 80 is pushed against the outer periphery. The shaping device may include a pressing member 3 as illustrated in FIG. 18.

Also, the same effects as those described in the first embodiment can be obtained in the present embodiment. In the present embodiment, since the number of pushing units 20 can be reduced, the configuration of the shaping device can be simplified. Thus, the number of components in the shaping device can be reduced.

### Fourth Embodiment

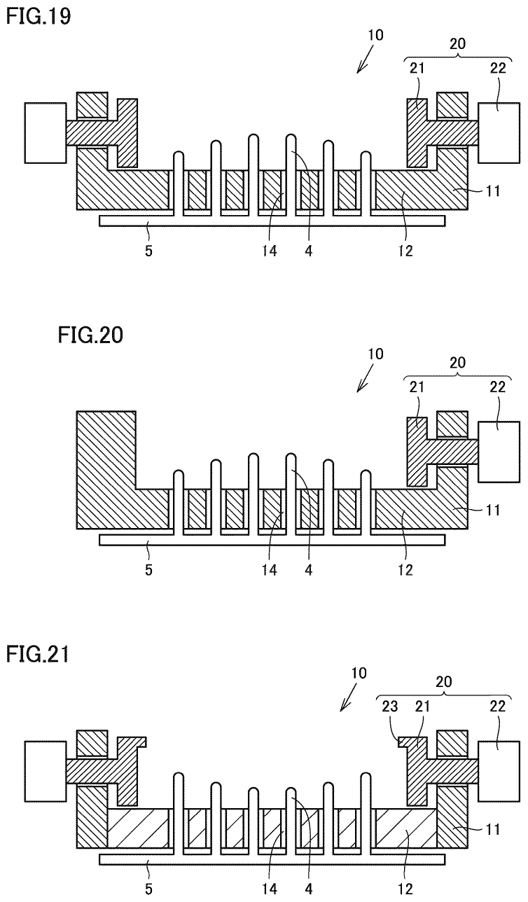

A shaping device according to a fourth embodiment of the present disclosure will be described with reference to FIGS. 19 and 20. FIG. 19 illustrates an object supporting unit 10 of the shaping device according to the present embodiment. In the shaping device according to the present embodiment, base 12 does not include a cooling unit. Outer periphery 11 and base 12 are formed into an integrated body from the same material. As described above, base 12 may not include a cooling unit. The cooling may be performed by another device provided at a position other than base 12. Alternatively, the cooling may be performed by naturally radiating heat to the surroundings, rather than by using a cooling unit that performs active cooling.

FIG. 20 illustrates an object supporting unit 10 of a modification of the shaping device according to the present embodiment. In the example illustrated in FIG. 20, pushing unit 20 is provided only at one side. Such a configuration may be employed.

Also, the same effects as those described in the first embodiment can be obtained in the present embodiment. In the present embodiment, since base 12 of object supporting unit 10 does not include a cooling unit, the structure of object supporting unit 10 can be simplified.

### Fifth Embodiment

A shaping device according to a fifth embodiment of the present disclosure will be described with reference to FIG. 21. FIG. 21 illustrates an object supporting unit 10 of the shaping device according to the present embodiment. In the shaping device according to the present embodiment, pushing unit 20 includes a stopper 23. Pushing tool 21 is provided with a stopper 23 which is a protrusion that limits upward displacement of object 80. More specifically, stopper 23 is provided as a protrusion protruding forward from an upper portion of a distal end surface of pushing tool 21. However, stopper 23 illustrated in the present embodiment is merely an example. Stopper 23 is not limited to the configuration illustrated in FIG. 21 as long as it can limit upward displacement of the outer edge of object 80. Stopper 23 is not limited to having one step as illustrated in FIG. 21, and may have two or more steps. Stopper 23 may be in the form of an inverted slope. Stopper 23 is not limited to a protrusion. For example, a non-slip region may be provided on a surface of pushing tool 21 that comes into contact with object 80, and this region may be used as stopper 23. Assuming an imaginary plane that connects upper ends of the plurality of support pins 4, the imaginary plane is convex downward.

In the present embodiment, since stopper 23 is provided in pushing tool 21, it is possible to prevent an end of object 80 from excessively slipping and thereby significantly shifting on object supporting unit 10 or prevent it from dropping out from object supporting unit 10.

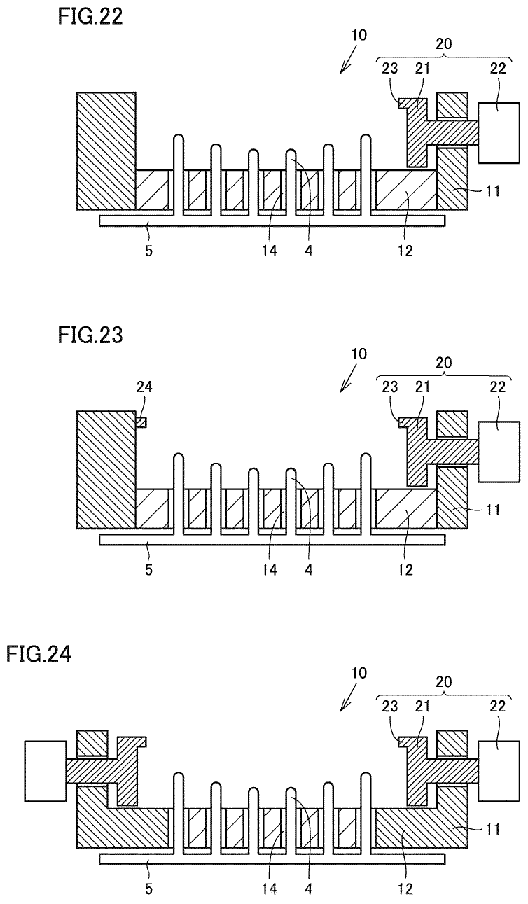

Although FIG. 21 illustrates an example in which pushing unit 20 is provided on both sides, in a first modification as illustrated in FIG. 22, pushing unit 20 may be provided only on one side. In the first modification illustrated in FIG. 22, one end of the object is pressed against outer periphery 11, but in order to prevent this end of object 80 from excessively sliding upward, in a second modification illustrated in FIG. 23, a stopper 24 may be provided on outer periphery 11 on the side where pushing unit 20 is not provided. Stopper 24 is provided as a protrusion protruding from an upper portion of an inner peripheral surface of outer periphery 11.

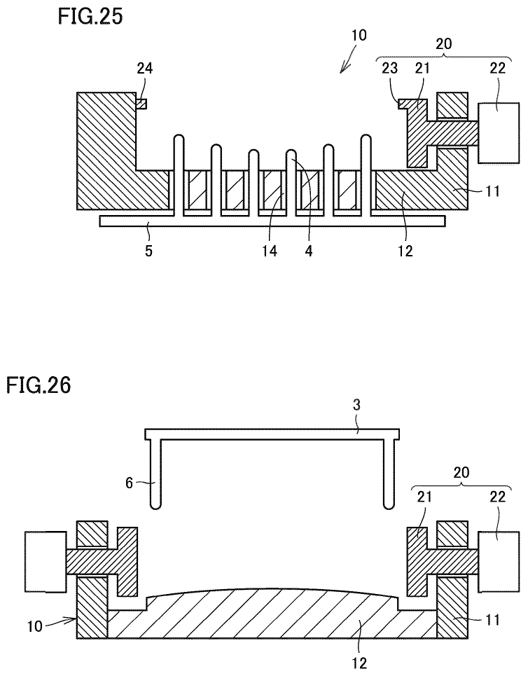

Although FIGS. 21 to 23 illustrate an example in which base 12 of object supporting unit 10 includes a cooling unit, as illustrated in a third modification of FIG. 24 or a fourth modification of FIG. 25, base 12 of object supporting unit 10 may not include a cooling unit. Since base 12 of object supporting unit 10 does not include a cooling unit, the structure of object supporting unit 10 can be simplified.

Assuming an imaginary plane that connects all upper ends of the plurality of support pins 4, the imaginary plane is preferably convex downward. According to this configuration, object 80 can be appropriately supported.

### Sixth Embodiment

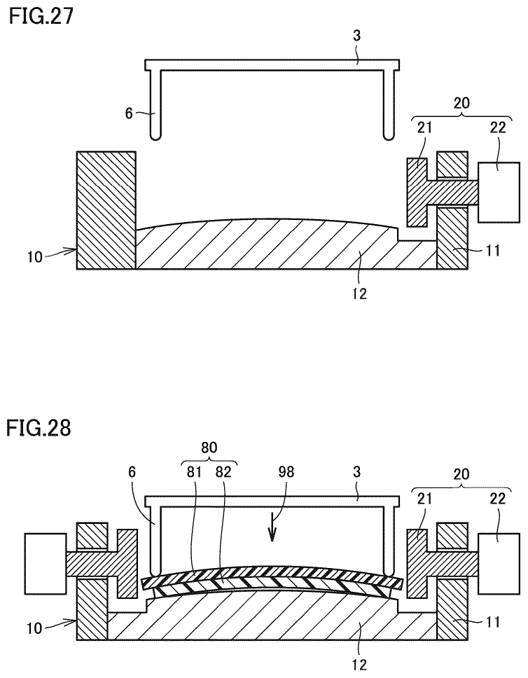

A shaping device according to a sixth embodiment of the present disclosure will be described with reference to FIGS. 26 and 27. FIG. 26 illustrates a shaping device according to the present embodiment. The shaping device according to the present embodiment does not include a plurality of support pins that support object 80. Base 12 has a convex or concave upper surface that comes into contact with object 80. As one example, as illustrated in FIG. 26, base 12 has a convex upper surface that comes into contact with object 80.

In a modification as illustrated in FIG. 27, pushing unit 20 may be provided only on one side of object supporting unit 10.

The operation of the shaping device according to the present embodiment will be described with reference to FIGS. 28 to 31.

First, as illustrated in FIG. 28, an object 80 is disposed on object supporting unit 10 and heated. When the heating is finished, object 80 is warped. Object 80 is supported by the convex upper surface of base 12. Pressing member 3 is lowered in the direction of arrow 98 to press the outer edge of object 80 downward. The floating position of object 80 is appropriately adjusted by pressing member 3.

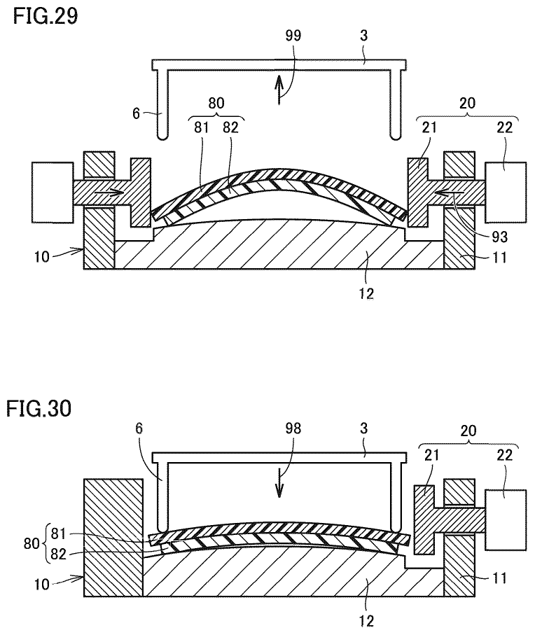

As indicated by arrow 99 in FIG. 29, pressing member 3 is lifted. Pushing tool 21 of pushing unit 20 on each side is moved forward as indicated by arrow 93 to sandwich object 80. As a result, object 80 is deflected. In this state, the cooling is performed. Thus, object 80 is shaped into a desired shape.

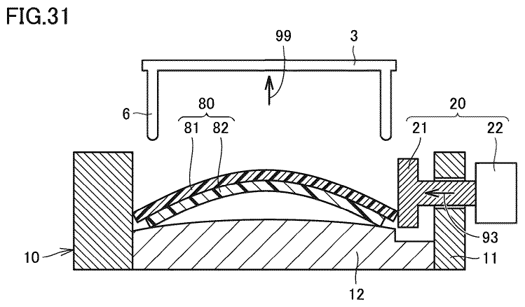

The same applies to the configuration according to a modification in which pushing unit 20 is provided only on one side of object supporting unit 10. In other words, as illustrated in FIG. 30, pressing member 3 is lowered in the direction of arrow 98 to press the outer edge of object 80 downward. The floating position of object 80 is appropriately adjusted by pressing member 3. As indicated by arrow 99 in FIG. 31, pressing member 3 is lifted. Pushing tool 21 of the pressing unit 20 is moved forward as indicated by arrow 93 to press object 80 against outer periphery 11. As a result, object 80 is deflected. In this state, the cooling is performed. Thus, object 80 is shaped into a desired shape.

### Seventh Embodiment

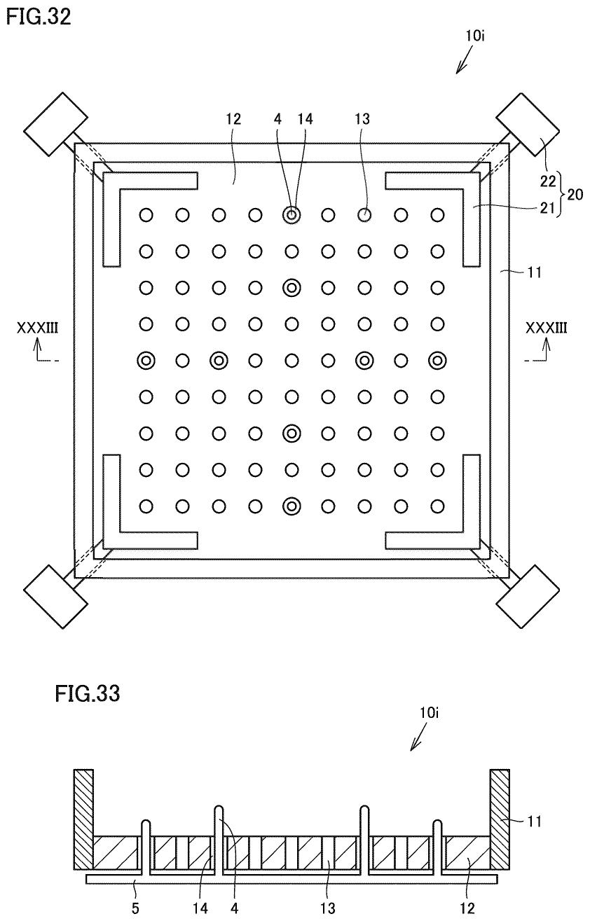

A shaping device according to a seventh embodiment of the present disclosure will be described with reference to FIGS. 32 to 35. FIG. 32 illustrates an object supporting unit 10i of the shaping device according to the present embodiment. The shaping device is configured to shape a square object 80. FIG. 33 is a cross-sectional view taken along line XXXIII-XXXIII in FIG. 32.

When the shape of object 80 is rectangular, since warpage is almost limited to such a manner that the long side deflects when viewed from the direction perpendicular to the long side, the warpage can be handled by pushing the short side of object 80 with pushing tool 21. However, when object 80 has a square shape, there is no long side or short side, and the warping direction of the object cannot be determined. In such an object 80, there may be a number of possible warping patterns. Therefore, when object 80 has a square shape, it is preferable to use object supporting unit 10i as described in the present embodiment.

The shaping device according to the present embodiment includes an object supporting unit 10i. Object supporting unit 10i has a square outer periphery 11. Each of the four corners of outer periphery 11 is provided with a pushing unit 20. Pushing unit 20 includes an L-shaped pushing tool 21 and a driving member 22. Pushing tool 21 and driving member 22 are connected by a shaft, and the shaft passes through outer periphery 11. However, the shape of pushing unit 20 illustrated in the present embodiment is merely an example. The shaft that passes through outer periphery 11 is merely an example. A notch may be formed on outer periphery 11 to install pushing unit 20. The shape of pushing unit 20 illustrated in the present embodiment is merely an example, and is not limited to thereto. For example, the structure of the shaft that connects pushing tool 21 to driving member 22 is not limited to that illustrated in the drawings.

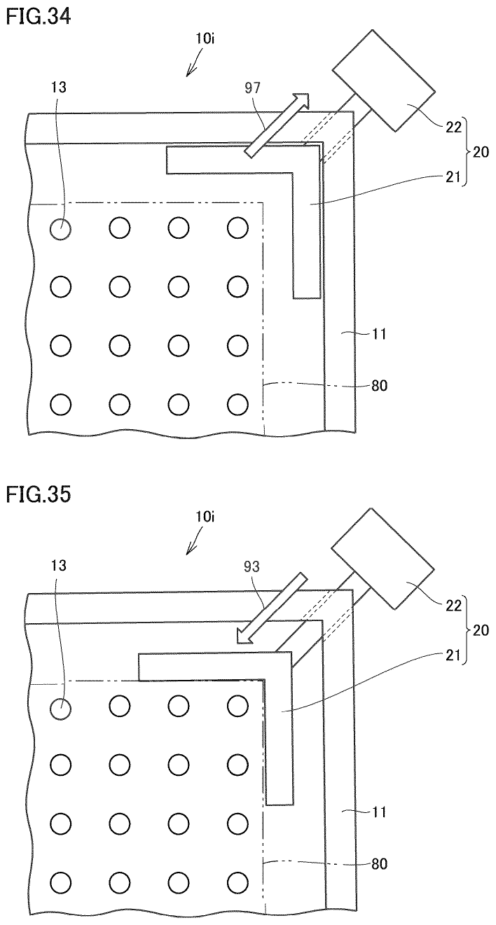

FIGS. 34 to 35 are enlarged views illustrating one corner of object supporting unit 10i. Hereinafter, the operation of pushing unit 20 will be described.

FIG. 34 illustrates a state in which pushing tool 21 is mostly moved backward. Pushing tool 21 is moved backward by the driving of driving member 22 as indicated by arrow 97. The profile of object 80 is indicated by a two-dot chain line. At this time, pushing tool 21 is sufficiently far away from object 80.

FIG. 35 illustrates a state in which pushing tool 21 is moved backward. Pushing tool 21 is moved backward by the driving of driving member 22 as indicated by arrow 93. Pushing tool 21 is brought into contact with a corner of object 80 to press object 80 in a diagonal direction of object 80.

As described above, the shaping device according to the present embodiment includes a pushing tool 21 that pushes a plate-shaped object 80, which is disposed in such a manner that one main surface thereof faces upward, from a side of object 80, and a heating unit 2 that heats object 80.

The term “pushing from a side” as used herein includes not only pushing a side of an object in a direction perpendicular to the side but also pushing a corner of the object in a diagonal direction. For example, in the case where object 80 is circular, “pushing object 80 from a side” includes pushing object 80 in the radial direction.

In the present embodiment, since pushing unit 20 including an L-shaped pushing tool 21 is provided at each corner of object supporting unit 10i of the shaping device, and each pushing tool 21 is configured to push one corner of object 80 in the diagonal direction, even when object 80 has a square shape, it can be appropriately shaped.

### Eighth Embodiment

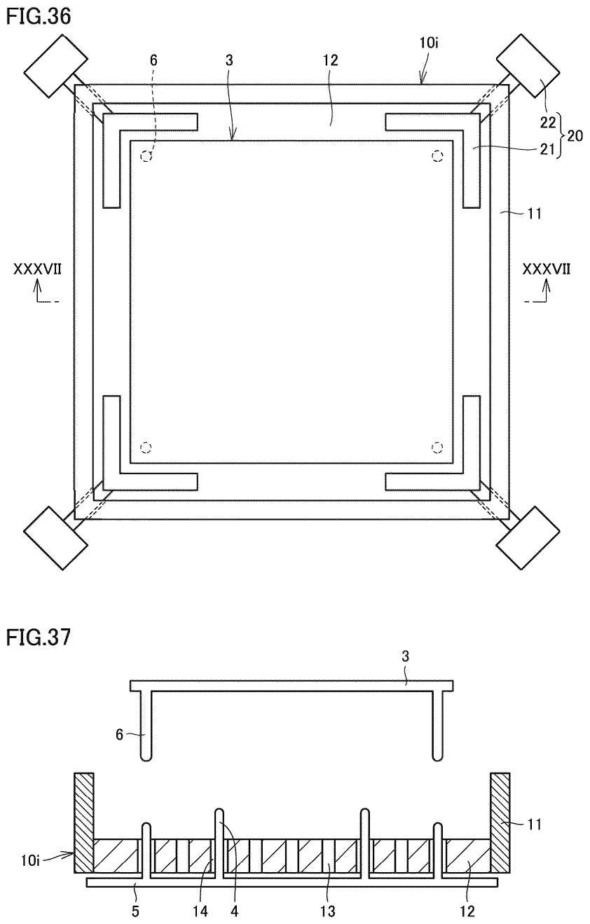

A shaping device according to an eighth embodiment of the present disclosure will be described with reference to FIGS. 36 and 37. FIG. 36 illustrates an object supporting unit 10i and a pressing member 3 of the shaping device according to the present embodiment. FIG. 37 is a cross-sectional view taken along line XXXVII-XXXVII in FIG. 36. The shaping device according to the present embodiment includes a pressing member 3 which includes projections 6 extending downward, and is configured to press object 80 downward by bringing the tip of each projection 6 into contact with object 80. As seen in a plan view of FIG. 36, four projections 6 are disposed at four corners of pressing member 3, respectively. In FIG. 36, since the four protrusions 6 are located on the back side of pressing member 3 and are not directly visible, they are indicated by broken lines.

Also, the same effects as those described in the seventh embodiment can be obtained in the present embodiment. Further, in the present embodiment, since pressing member 3 is provided, object 80 can be more reliably held at a desired position.

### Modification

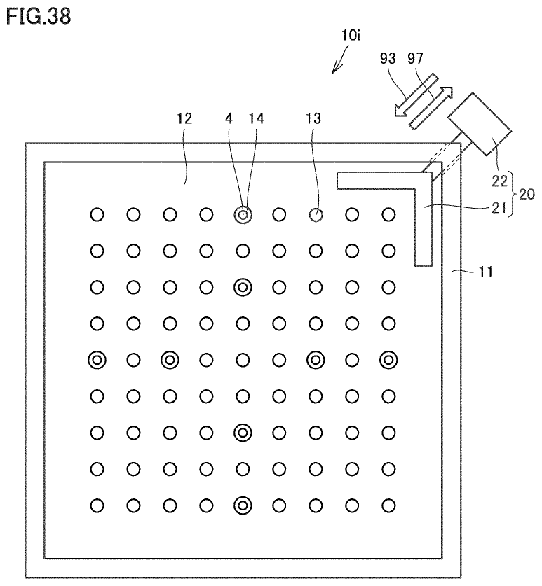

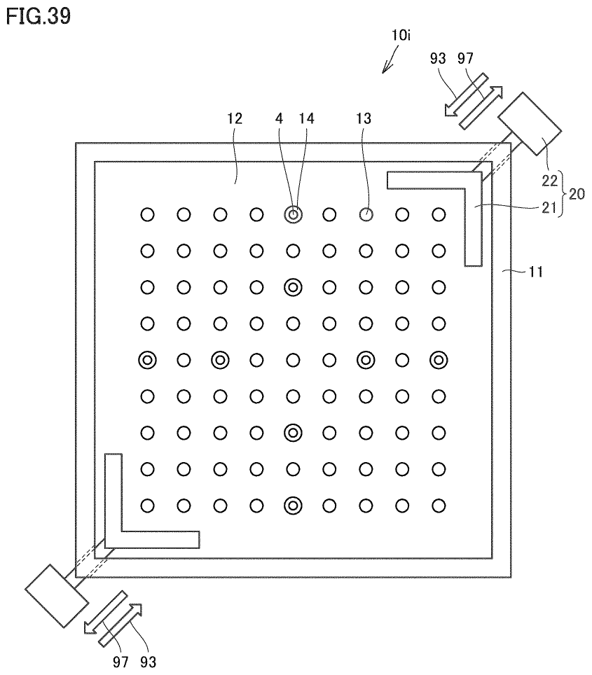

A modification of the shaping device applicable to any of the seventh and eighth embodiments will be described with reference to FIGS. 38 and 39.

In the example illustrated in FIG. 38, a pushing unit 20 is provided only on one corner of an object supporting unit 10i having a square shape. A pushing tool 21 included in pushing unit 20 can be moved forward as indicated by arrow 93 or backward as indicated by arrow 97 by the driving of driving member 22. When pushing tool 21 is moved forward, pushing tool 21 pushes object 80 in the diagonal direction, and thereby object 80 is pressed against a corner of outer periphery 11 at a position facing the pressing unit 20. In this way, object 80 is sandwiched between pushing tool 21 and outer periphery 11 and held by the same. According to the shaping device having such a configuration, the square-shaped object 80 can be appropriately shaped.

In the example illustrated in FIG. 39, a pushing unit 20 is provided at each of two opposing corners of an object supporting unit 10i having a square shape. A pushing tool 21 included in each of the two pushing units 20 can be moved forward as indicated by arrow 93 or backward as indicated by arrow 97 by the driving of driving member 22. When the two pushing tools 21 are moved forward, object 80 is sandwiched by the two pushing tools 21 in the diagonal direction and held by the same. According to the shaping device having such a configuration, the square-shaped object 80 can be appropriately shaped.

The embodiments described above may be combined appropriately.

It should be understood that the embodiments disclosed herein are illustrative and non-restrictive in all respects. The scope of the present disclosure is defined by the terms of the claims, and is intended to include any modifications within the scope and meaning equivalent to the terms of the claims.

### ASPECTS

### First Aspect

A shaping device comprising:
a pushing tool that pushes a plate-shaped object, which is disposed in such a manner that one main surface thereof faces upward, from a side of the object; and
a heating unit that heats the object

### Second Aspect

The shaping device according to the first aspect, wherein the pushing tool is provided with a stopper which is a protrusion that limits upward displacement of the object.

### Third Aspect

The shaping device according to the first aspect or the second aspect, further comprising:
a base that supports the object.

### Fourth Aspect

The shaping device according to the third aspect, wherein the base includes a cooling unit that cools the object.

### Fifth Aspect

The shaping device according to the third aspect or the fourth aspect, wherein the base has a convex or concave upper surface that comes into contact with the object.

### Sixth Aspect

The shaping device according to any one of the first aspect to the fifth aspect, further comprising:
a suction device that suctions the object downward.

### Seventh Aspect

The shaping device according to any one of the first aspect to the sixth aspect, further comprising:
a plurality of support pins protruding upward to support the object.

### Eighth Aspect

The shaping device according to the seventh aspect, wherein the plurality of support pins are movable in the vertical direction.

### Ninth Aspect

The shaping device according to any one of the first aspect to the eighth aspect, further comprising:
a pressing member that includes a projection extending downward, and
a tip of the projection is brought into contact with the object to press the object downward.

### Tenth Aspect

The shaping device according to the seventh aspect or the eighth aspect, wherein assuming an imaginary plane that connects upper ends of all of the plurality of support pins, the imaginary plane is convex upward.

### Eleventh Aspect

The shaping device according to the seventh aspect or the eighth aspect, wherein assuming an imaginary plane that connects upper ends of all of the plurality of support pins, the imaginary plane is convex downward.

### REFERENCE SIGNS LIST

2: heating unit; 3: pressing member; 4: support pin; 5: support pin holding member; 6: protrusion; 10, 10i: object supporting unit; 11: outer periphery; 12: base; 13: suction port; 14: through hole; 20: pushing unit; 21: pushing tool; 22: driving member; 23, 24: stopper; 80: object; 81: first resin layer; 82: second resin layer; 91, 92, 93, 94, 95, 96, 97, 98, 99: arrow; 101, 102: shaping device.

1. A shaping device comprising:
a pushing tool configured to push a plate-shaped object, which is disposed in such a manner that one main surface thereof faces upward, from a side of the object; and
a heater configured to heat the object.

2. The shaping device according to claim 1, wherein the pushing tool comprises with a stopper which is a protrusion that limits upward displacement of the object.

3. The shaping device according to claim 1, further comprising:
a base that supports the object.

4. The shaping device according to claim 3, wherein the base comprises a cooler configured to cool the object.

5. The shaping device according to claim 3, wherein the base has a convex or concave upper surface that contacts the object.

6. The shaping device according to any one of claim 1, further comprising:
a suction device that configured to suction the object downward.

7. The shaping device according to any one of claim 1, further comprising:
a plurality of support pins protruding upward so as to support the object.

8. The shaping device according to claim 7, wherein the plurality of support pins are movable in the vertical direction.

9. The shaping device according to any one of claim 1, further comprising:
a pressing member comprising a projection extending downward,
wherein a tip of the projection is contacts the object when pressing the object downward.

10. The shaping device according to claim 7. wherein an imaginary plane that connects upper ends of all of the plurality of support pins is convex upward.

11. The shaping device according to claim 7. wherein an imaginary plane that connects upper ends of all of the plurality of support pins is convex downward.
